(19) United States
(12) Patent Application Publication
(10) Pub. No.: US 2011/0006311 A1
(43) Pub. Date: Jan. 13, 2011

(54) PHOTOSENSITIVE STRUCTURE AND APPARATUS INCLUDING SUCH A STRUCTURE

(76) Inventors: Benjamin James Hadwen, Oxford (GB); Michael Paul Coulson, Oxford (GB)

Correspondence Address: MARK D. SARALINO ( SHARP );RENNER, OTTO, BOISSELLE & SKLAR, LLP, 1621 EUCLID AVENUE, 19TH FLOOR, CLEVELAND, OH, 44115, US

(21) Appl. No.: 12/934,126

(22) PCT Filed: Apr. 15, 2009
(86) PCT No.: PCT/JP2009/057943

§ 371 Date: Sep. 23, 2010

(30) Foreign Application Priority Data
Apr. 28, 2008 (GB) 0807649.9

(51) Int. Cl. H01L 27/146; H01L 31/12

(52) U.S. Cl. 257/84; 257/292; 257/E27.133; 257/E33.077

(57) ABSTRACT

A photosensitive structure comprises a plurality of photosenstivie regions (124) which are electrically in series. A light shading layer comprises a plurality of electrically conductive regions (501) disposed so as to shade the photosensitive regions (124) from light incident on a major surface of the structure. The conductive regions (501) are electrically isolated from each other.

### TECHNICAL FIELD

The present invention relates to a photosensitive structure and to an apparatus including such a structure. Such an apparatus may, for example, comprise photosensor devices that are integrated into an active matrix liquid crystal device (AMLCD).

### BACKGROUND ART

An ambient light sensor (ALS) may be integrated on an AMLCD display substrate as shown in FIG. 1 of the accompanying drawings.

FIG. 2 of the accompanying drawings shows a simplified cross-section of a typical AMLCD. The backlight 101 is a light source used to illuminate the display. The transmission of light through the display, from the backlight 101 to the viewer 102, is controlled by the use of electronic circuits made from thin film transistors (TFTs). The TFTs are fabricated on a glass substrate (known as the TFT glass 103) and are operated so as to vary the electric field through the Liquid Crystal (LC) 104 layer. This in turn varies the optical properties of the LC material and thus enables the selective transmission of light through the display, from the backlight 101 through to the viewer 102.

In many products which utilise displays (e.g. mobile phones, Personal Digital Assistants (PDAs)) it is found to be useful to control the light output of the backlight according to ambient illumination conditions. For example under low ambient lighting conditions it is desirable to reduce the brightness of the display backlight and hence also the brightness of the display. As well as maintaining the optimum quality of the display output image, this allows the power consumed by the backlight to be minimised.

In order to vary the intensity of the backlight in accordance with the ambient lighting conditions, it is necessary to have some means for sensing the level of ambient light. An ambient light sensor used for this purpose could be separate from the TFT glass substrate. However often there are several advantages of integrating the ALS onto the TFT glass substrate (“monolithic integration”), for example in reducing the size, weight and manufacturing cost of the product containing the display.

A typical practical ambient light sensor system as shown in FIG. 1 of the accompanying drawings will contain the following elements:
(a) A photodetection element (or elements) capable of converting incoming light to electrical current. An example of such a photodetection element is a photodiode 2.
(b) Bias circuitry (ambient light sensor drive circuit 3) to control the photodetection element(s) and sense the photo-generated current.
(c) Output circuitry 4 to supply an output signal (analogue or digital) representing the measured ambient light level.
(d) A means of adjusting the display operation (backlight controller 5) based on the measured ambient light level, for example by controlling the intensity of the backlight 101.

In the case of an AMLCD with a monolithically integrated ambient light sensor, the basic photodetection device used must be compatible with the TFT process used in the manufacture of the display substrate. A well-known photodetection device compatible with the standard TFT process is the lateral, thin-film, polysilicon P-I-N diode, a two terminal device with an anode 8 and cathode 9 whose circuit representation is shown in FIG. 3 of the accompanying drawings. The typical structure of such a device is as shown in FIG. 4 of the accompanying drawings. This device comprises of a p-type region of semiconductor material (in this case polysilicon) which forms the anode 8 of the device and an n-type region of semiconductor material which forms the cathode 9 of the device. Between the n- and p-type regions is a region of intrinsic or lightly doped semiconductor material (silicon) 7. This forms the photosensitive part of the device, being capable of converting incoming light to an electrical current.

To operate such a photodiode, a potential difference must be applied between the two photodiode terminals, the anode 8 and the cathode 9. The typical current-voltage (IV) characteristics of a photodiode are shown in FIG. 5 of the accompanying drawings, with the device in darkness 12 and with the device illuminated by some light level A 13. Here the applied photodiode bias is the potential difference between the anode and the cathode.

It can be seen from FIG. 5 of the accompanying drawings that illuminating the device changes the current flowing through it for any given operating bias. For operation of the device at a given bias voltage, the current that is generated with the device in darkness can be termed the “leakage current” (or “dark current”) of the device. The current that is generated with the device illuminated can be termed the “light current”. This consists of the sum of the leakage current and that portion of the current which is generated in response to the incident light (this latter portion being termed “photocurrent”).

Photodiodes fabricated in a polysilicon TFT process have in general a low sensitivity for two principal reasons:
1. The photo current is generally small, typically being limited by the thickness of the thin film semiconductor material.
2. The leakage current is generally large, typically due to the high density of defect states in the semiconductor material.

In many applications the sensitivity limit of the photodiode is determined by the relative contributions of the photocurrent and the leakage current. If the photocurrent is smaller than the leakage current, then it becomes difficult to detect. Additionally, the leakage current is generally very strongly temperature dependent, increasing with increasing temperature. Accordingly, an ambient light sensor whose sensing element is a thin-film polysilicon photodiode is likely to exhibit relatively low sensitivity, especially at higher operating temperatures.

It is a requirement of an AMLCD with a monolithically integrated ambient light sensor that some provision is made to prevent direct illumination of the photosensor element 2 by the display backlight 101. The most convenient way to implement this is by means of an opaque light shading (LS) layer 501 positioned between the backlight and the photosensor element shown FIG. 6 of the accompanying drawings.

One possible means for realising a suitable LS layer is the use of an additional material placed in between the TFT glass substrate and the backlight, for example black tape or black paint. The disadvantage of such a method is that it may add to the thickness or to the cost of the display module. A further significant disadvantage is that it may be difficult to mechanically align the LS layer between the backlight and photosensor element with sufficient precision. This is particularly likely to be the case if the photosensor element is required to be located close to the display active area, since it is necessary that the region covered by the LS layer does not intrude into the active area so as not to impair the performance of the display.

It is therefore often found to be advantageous to monolithically integrate the LS layer onto the TFT glass substrate, shown in FIG. 7 of the accompanying drawings, 0.20 as for example is disclosed in EP1511084A2. A possible method for fabricating a TFT glass substrate with integrated LS layer is described in U.S. Pat. No. 6,750,476. For ease of compatibility with standard TFT processing, it is generally found to be convenient to form the light shading layer from a layer of deposited metal, for example aluminium or molybdenum. A flowchart showing a typical AMLCD process which includes an LS layer is shown in FIG. 8 of the accompanying drawings.

U.S. Pat. No. 6,750,476 also describes a method for making a contact between the LS layer and other metal layers available in the standard TFT process.

It is furthermore known that the LS layer may have applications other than blocking the path of light from the backlight to a photosensor element. U.S. Pat. No. 6,556,265 describes how a light shading layer can be used to reduce the photo-induced leakage current in the display pixel TFT. It is possible for the LS layer to be electrically isolated from all other conductive layers and it is also possible to form contacts from it to other metal or semiconductor layers available in the process. U.S. Pat. No. 6,556,265 also describes a method for reducing the resistance of the bus lines in the display driver circuit by making contacts to the LS layer from the source driver line. U.S. Pat. No. 7,199,853 describes how the LS layer can be used to form one of the plates of a capacitor which can be used for charge storage in the display pixel.

A thin film photodiode such as has been described can be represented by the equivalent circuit of FIG. 9 of the accompanying drawings where a voltage dependent current source I(V) 502 is arranged in series with a resistance element R 504 and with a capacitance C 506 in parallel with these elements.

The capacitive element C arises from two main sources:
(i) The capacitance of the diode element, as formed within the semiconductor material itself. This is generally referred to as the diode “junction capacitance” and methods for calculating it are well described in standard semiconductor physics textbooks;
(ii) Parasitic capacitance elements. These arise for example due the capacitance between the source electrode metal used to contact to the semiconductor at the anode and cathode of the sensor.

For a well designed thin film photodiode the junction capacitance is generally small compared to the parasitic anode-to-cathode capacitance and the parasitic capacitance dominates. In the case where the thin film photodiode has a monolithically integrated LS layer, this parasitic capacitance is in turn dominated by the capacitive effect due to the presence of this LS layer. This is shown in FIG. 11 of the accompanying drawings. The photodiode anode and photodiode cathode both have a large parasitic capacitance to the LS layer. The net result is that the LS layer introduces a parasitic capacitance between anode and cathode equal to the anode-LS and cathode-LS capacitors connected in series.

The additional parasitic capacitance introduced by the inclusion of the LS layer may also have deleterious consequences for the performance of devices that are not intended as photosensor elements and where the LS structure has been included to limit photo-induced leakage current. An example of such a device would be a thin film transistor (TFT) designed to have minimal leakage current. An example of such a device is the “pixel TFT”, a switching element that is incorporated into each pixel element of an AMLCD matrix. Such a device commonly includes a Lightly Doped Drain (LDD) structure to minimise enhancement of thermally-generated leakage current by the electric field. It is also common to realise the switch using multiple TFT devices connected in series. A simplified diagram of series connected LDD-TFTs is shown in FIG. 10 of the accompanying drawings. The LDD TFT comprises heavily-doped n-type (N+) regions of silicon 160, moderately doped n-type (N) regions of silicon 162 and lightly doped regions of p-type (P−) silicon 164. The gate electrode structure 166 extends over the entirety of the P-region and over a part of the N region at each side.

An example of a pixel TFT structure which utilises multiple series devices and also has an LDD structure is given in U.S. Pat. No. 6,310,670.

A disadvantage of this structure is that, whilst thermally-induced leakage current may be reduced to very low levels, the resulting structure is photosensitive and illumination from the display backlight may induce an unwanted photo-generated leakage current.

An LS structure may be effective in reducing the photo-generated leakage current by blocking the path of light incident from the backlight. However this advantage may be outweighed by the accompanying disadvantages associated with the additional device capacitance, which may deleteriously increase parasitic charge injection and also the switching time of the device.

A photodiode is not the only possible photosensor device for converting incoming light to current. One alternative well known possibility is a phototransistor, whose drain-source current is a function of the incident light level. Phototransistors can be operated with the gate connected to either the drain, the source, some other external bias supply or with the gate left floating.

A further possible photosensitive device is a photo-resistor (a device whose electrical resistance is a function of the incident light level), and various other possibilities also exist.

To maximise the sensitivity of a photodetection element such as a thin film photodiode it is advantageous to bias the photodetection element such that the ratio of the photocurrent to the leakage current is maximised, i.e. at the built-in voltage of the device.

FIG. 12 of the accompanying drawings shows a well known circuit implementation for biasing a photosensor device at zero volts and measuring the current generated. This circuit contains the following elements:
A photodiode 7 which is exposed to ambient light. The parasitic photodiode capacitance is shown 120 and denoted Cpar.
An operational amplifier 51 of standard construction.
An integration capacitor C_{INT} 52.
A switch S1 53.
An Analogue to Digital Converter (ADC) 81 of standard construction.

The circuit elements are connected as follows. The non-inverting terminal of the operational amplifier 51 is connected to the anode of the photodiode 7 which is connected to ground. The inverting terminal of the operational amplifier 51 is connected to the cathode of the photodiode 7. The integration capacitor 52 is connected between the inverting terminal and the output of the operational amplifier 51. The switch S1 53 is connected between the terminals of the integration capacitor 52. The ADC 81 is connected to the output of the operational amplifier 51.

The operation of this circuit is as follows:
Prior to the beginning of the integration period, the switch S1 53 is closed. This resets the potential across the integration capacitor C_{INT} 52 to 0 Volts.
At the beginning of the integration period, the switch S1 53 is opened.
The operational amplifier 51 operates so that (in the ideal case) the potential difference between the inverting and non-inverting input terminals is zero. As a consequence a potential of zero volts is developed at the non-inverting input of the operational amplifier 51.
Since the cathode of the photodiode 7 is at 0 Volts, a potential difference of zero volts is developed across the terminals of the photodiode 7.
During the integration period the detection photodiode generates a current I_{P} according to the intensity of ambient light incident upon it. This current is then integrated onto the integration capacitor C_{INT}.
The change of voltage at the output of the operational amplifier 51 between the start and the end of the integration period is then sampled. This change in voltage is equal to I_{P}/C_{INT} multiplied by the integration time.
The voltage level at the output of the amplifier is then converted to a digital output by the ADC 81. This digital output then represents the measured ambient light level.

The parasitic capacitance Cpar 120 can hinder the operation of this circuit in two ways. Firstly it can result in a low impedance path at high frequencies from the inverting terminal of the operational amplifier 51 to ground. This can cause the amplifier to become unstable under circumstances when the reset switch S1 53 is closed. Secondly, if Cpar is larger than C_{INT}, any noise coupled onto the inverting terminal of the operational amplifier 51, e.g. from the AMLCD driver circuitry, will be multiplied to the output of the operational amplifier 51 according to the ratio Cpar/C_{INT}. As a consequence, for the circuit of FIG. 12 to work well and be capable of detecting small amounts of photocurrent it is desirable for Cpar to be as small as possible.

Practical implementations of the circuit of FIG. 12 generally require the bias across the terminals of the photodiode to be maintained at zero to a fairly high degree of precision in order to maximise the sensitivity to incident ambient light. In practice, accurate implementation of the circuit of FIG. 12 may be difficult since the circuit components are non ideal. This is particularly the case when the circuit components are required to be integrated onto the TFT substrate. GB2443204 discloses a method for easing the precision biasing requirements by series connecting a number of photodiode elements in series, as shown in FIG. 13 of the accompanying drawings. By series connection of multiple sensor devices, the biasing requirements are eased. One known method for series connecting multiple photosensor devices is shown in FIG. 14 of the accompanying drawings. P-I-N photodiodes are formed in the thin film semiconductor layer by creating P+ doped semiconductor regions 122, lightly doped semiconductor regions 124 (which may be P− or N−) and N+ doped semiconductor regions 126. The semiconductor layer is separated from the LS layer 501 by an insulating oxide layer 136. Contacts 130 can be formed through the insulating interlayer dielectric 138 to connect the source electrode (SE) 132 to the N+ and P+ doped semiconductor regions. Thus, by appropriate patterning of the SE layer, series connected devices can be formed as shown.

An alternative method of forming series connected photodiodes has also been disclosed in an unpublished patent application, using the structure shown in FIG. 15 of the accompanying drawings. Here, the anode of one photodiode is connected to the cathode of the next photodiode by forming adjacent P+ and N+ doped regions. The resulting structure is therefore P-I-N-P-I-N- . . . etc, formed within a single silicon island. With a large number of such devices in series such that the applied bias across each individual P-N region is small, these P-N junctions, whilst essentially being diodes, have IV characteristics like a resistor, so that the P-N region approximates to a contact structure. It does not matter that the effective “resistance” of the PN structure is large since the series connected devices are only required to pass a relatively small photocurrent and so the potential drop across it is small. The advantage of this structure compared with that of FIG. 14 is that a larger number of photodiodes can be packed into a given area since less space is required to form the P-N structure than is needed to create contacts to the SE layer.

In the case of series connected photodiodes 258, 260, 262, 264 having an LS layer that forms a continuous conductive island, shown in FIG. 16 of the accompanying drawings, the parasitic capacitance can be estimated as follows. Let us suppose a symmetrical structure so that the capacitance of each photodiode anode and each photodiode cathode to the LS layer is C. To first order, the total capacitance CTOT between the anode 150 of the first photodiode 258 and the cathode 152 of the Nth photodiode 264 is that due to the first capacitor 154 in series with the last capacitor 156 which is equal to:

$${C}_{TOT} = \frac{1}{( 1 / C ) + ( 1 / C )} = \frac{C}{2} \qquad ( 1 )$$

As well as obtaining a sufficiently high ratio of photocurrent to leakage current, a further practical difficulty in many applications is the requirement to compensate the light measuring circuit to offset for the effects of unwanted (“stray”) light. For example in an ALS integrated in an AMLCD, the photosensor element may well be subject to stray light in addition to the ambient light that is being detected. Such stray light may originate (for example) from the display backlight and find its way into the photodiode, for example by means of single or multiple reflections within the glass substrate or from reflective structures (such as metal layers) surrounding the photodiode. The effects of stray light are a particular concern when the light sensor is integrated into the display as, even with careful design, minimising the stray light to levels comparable to or below the lowest detectable ambient light levels may in practice be very difficult. A number of compensation schemes for correcting a photosensor output to deal with the problems of leakage current are possible. A convenient method for doing this invokes the use of a second reference photosensor element which is shielded from ambient light (as well as direct illumination from the backlight). Many implementations of this are possible, for example as described in EP1394 859A2, JP Patent Application JP2005-132938 (Sharp) and GB2448869. The example structure of FIG. 17 of the accompanying drawings shows two photosensors, the first photosensor 7, termed the detection photosensor being of a previously described construction and being exposed to ambient illumination, and a second photosensor, termed the reference photosensor 142 which is identical except in that an additional opaque layer 144 is used over the photosensitive region to block ambient light.

An example circuit for measuring an ambient light level that has been corrected for the effects of stray light is shown in FIG. 18 of the accompanying drawings. This circuit contains the following elements:
A photodiode 7 which is exposed to ambient light. The parasitic photodiode capacitance is shown at 120 and denoted Cpar.
A second photodiode 142 which has an opaque light blocking layer 144 to shield it from ambient light. The parasitic photodiode capacitance is shown at 141 and denoted Cpard.
An operational amplifier 51 of standard construction.
An integration capacitor C_{INT} 52.
A switch S1 53.
An Analogue to Digital Converter (ADC) 81 of standard construction.

The circuit elements are connected as follows. The non-inverting terminal of the operational amplifier 51 is connected to the anode of the photodiode 7 which is connected to the cathode of the second photodiode 142 which is connected to ground. The inverting terminal of the operational amplifier 51 is connected to the cathode of the photodiode 7 and to the anode of the second photodiode 142. The integration capacitor is connected between the inverting terminal and the output of the operational amplifier 51. The switch S1 53 is connected between the terminals of the integration capacitor 52. The ADC 81 is connected to the output of the operational amplifier 51.

The operation of this circuit is then exactly as has already been described for the circuit of FIG. 12 with the current integrated onto the integration capacitor in this case being equal to the current from the detection photodiode 7 minus the current from the reference photodiode 142.

### SUMMARY OF INVENTION

According to a first aspect of the invention, there is provided a photosensitive structure comprising a plurality of photosensitive regions which are electrically in series and a first light shading layer comprising a plurality of electrically conductive regions disposed so as to shade the photosensitive regions from light incident on a first major surface of the structure, the conductive regions being electrically isolated from each other.

The photosensitive regions may extend laterally parallel to the first major surface. The photosensitive regions may comprise a plurality of lateral semiconductor junctions.

The photosensitive regions may comprise PIN diodes.

The photosensitive regions may comprise thin film transistors. The thin film transistors may comprise part of a pixel circuit of an active matrix device.

The photosensitive regions may comprise photosensor elements.

The structure may comprise a second light shading layer comprising a plurality of electrically conductive regions disposed so as to shade the photosensitive regions from light incident on a second major surface of the structure and electrically isolated from each other.

The conductive regions may comprise metallisation.

The conductive regions may be electrically isolated from the rest of the structure.

At least one of the conductive regions may be arranged to be connected to a predetermined potential. The at least one conductive region may be connected via a capacitive connection.

Each of the conductive regions of the first light shading layer may be associated with a respective one of the photosensitive regions.

At least one of the conductive regions of the first light shading layer may be arranged to shade at least two of the photosensitive regions from light incident on the first major surface.

The structure may be formed on an active matrix substrate.

According to a second aspect of the invention, there is provided an ambient light sensor comprising a structure according to the first aspect of the invention.

The sensor may comprise a further structure according to the first aspect of the invention arranged to act as a reference.

According to a third aspect of the invention, there is provided an apparatus including a structure according to the first aspect of the invention or a sensor according to the second aspect of the invention.

The apparatus may comprise a liquid crystal device.

The apparatus may comprise a display. The apparatus may comprise a backlight, the first light shading layer being disposed between the photosensitive regions and the backlight.

It is thus possible to provide an arrangement in which parasitic diode capacitance between an anode and a cathode due to the LS layer is substantially reduced. This makes the implementation of detection circuitry required to detect the current generated by a photosensor element considerably easier to realise, particularly so in the case where the current is being sensed by circuitry integrated onto a TFT-substrate.

The foregoing and other objectives, features, and advantages of the invention will be more readily understood upon consideration of the following detailed description of the invention, taken in conjunction with the accompanying drawings.

### BRIEF DESCRIPTION OF DRAWINGS

FIG. 1 shows prior art: an AMLCD with integrated ambient light sensor;

FIG. 2 shows prior art: a cross section of a typical AMLCD;

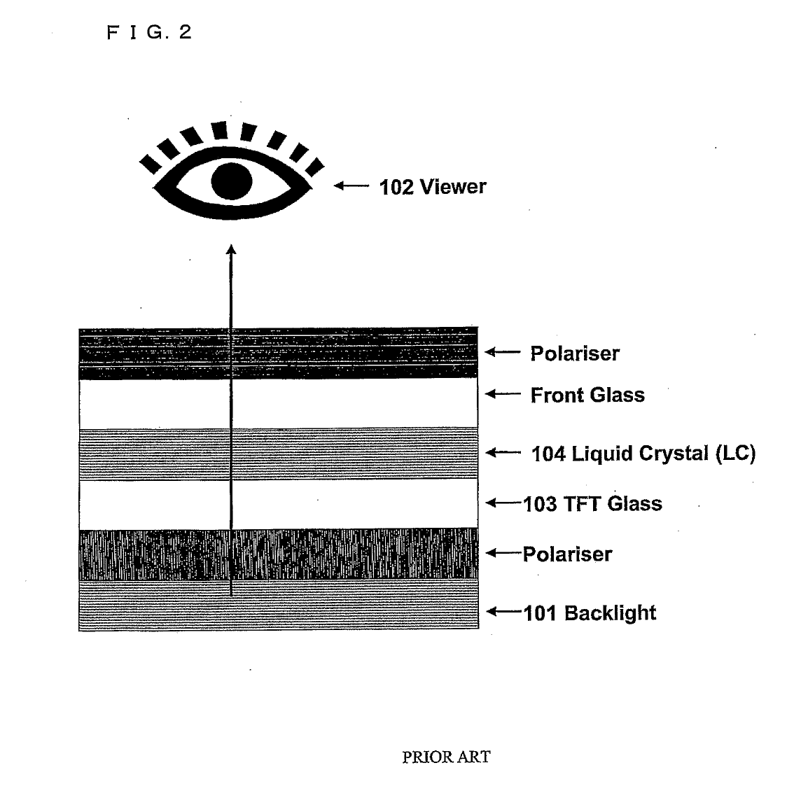

FIG. 3 shows prior art: a circuit representation of a PIN diode;

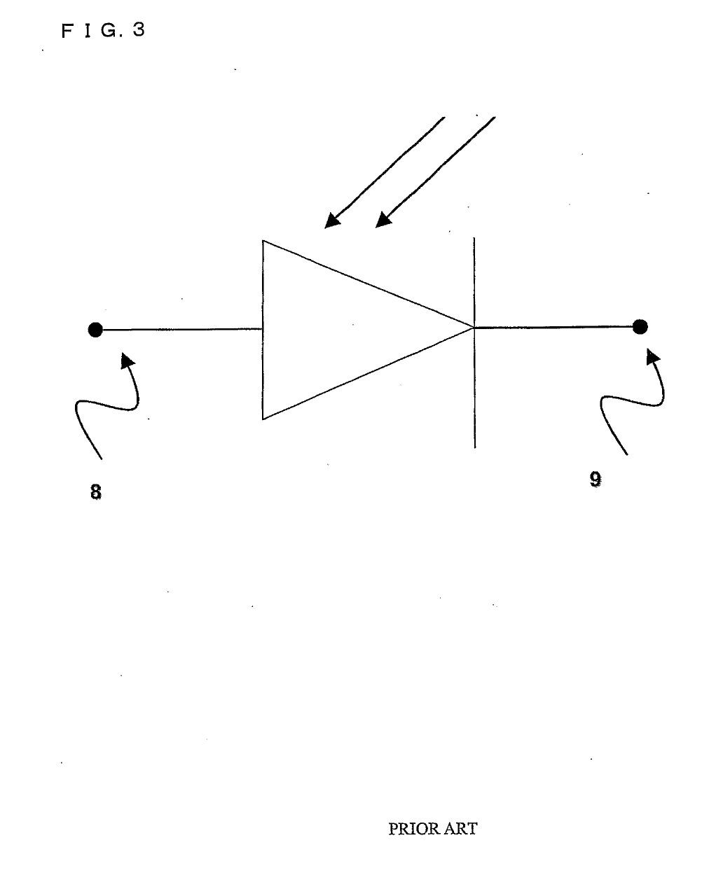

FIG. 4 shows prior art: a typical structure of a lateral thin-film PIN diode;

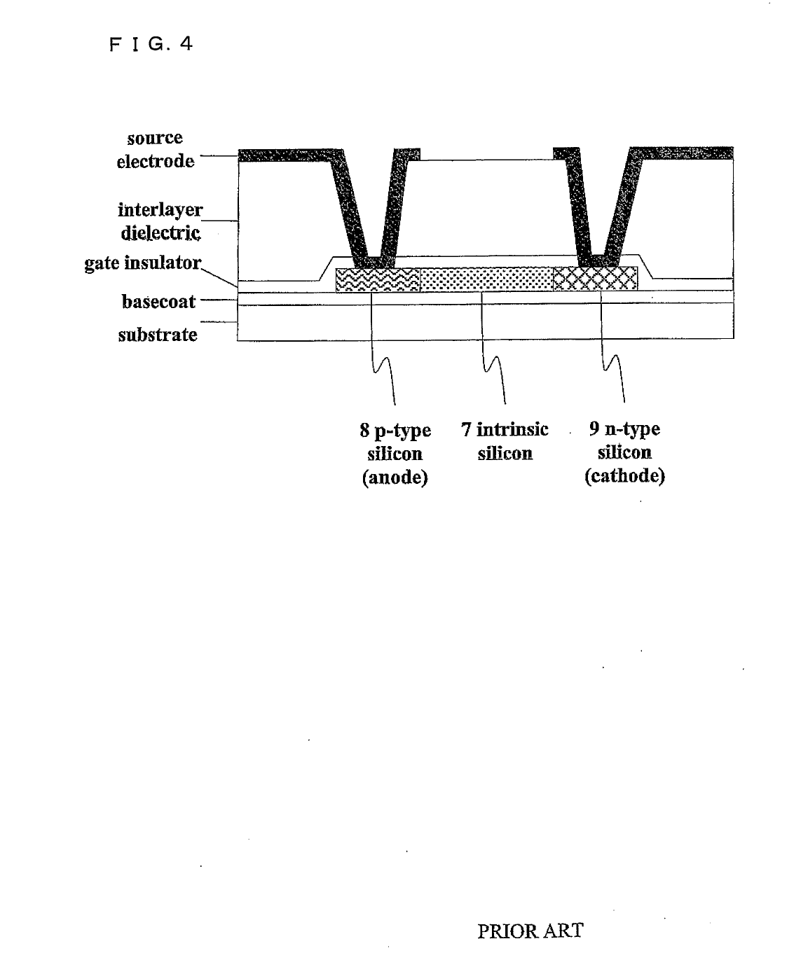

FIG. 5 shows prior art: the typical IV characteristics of a lateral thin film PIN diode;

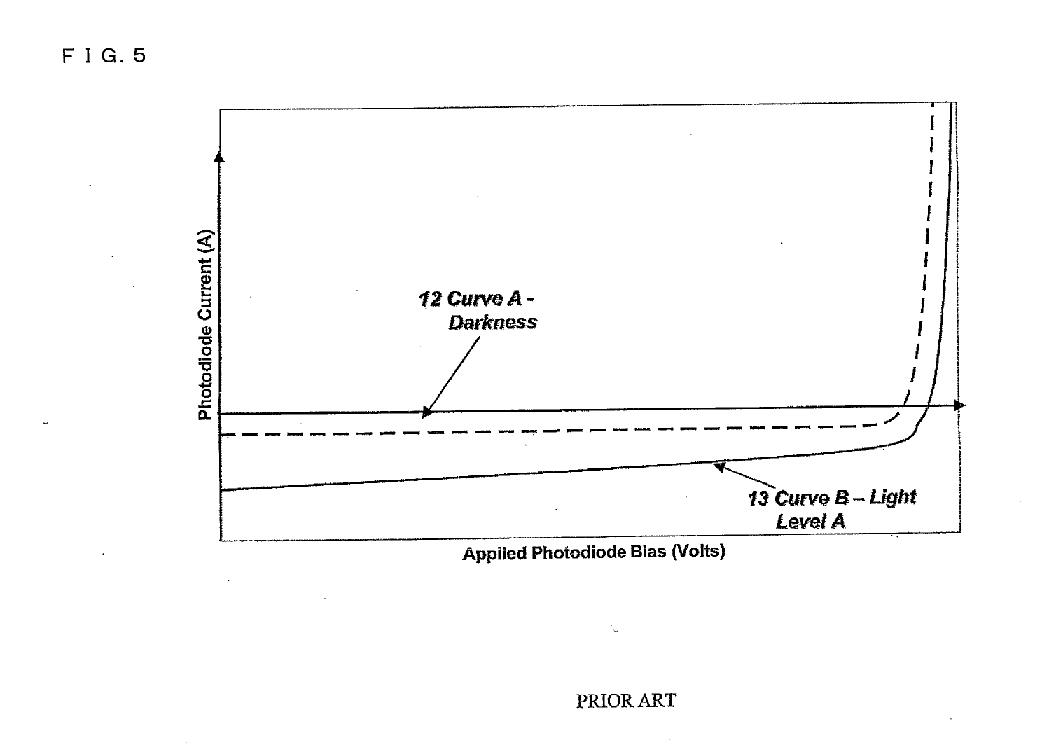

FIG. 6 shows prior art: an example cross section of an AMLCD with integrated photodiode and a light shading layer;

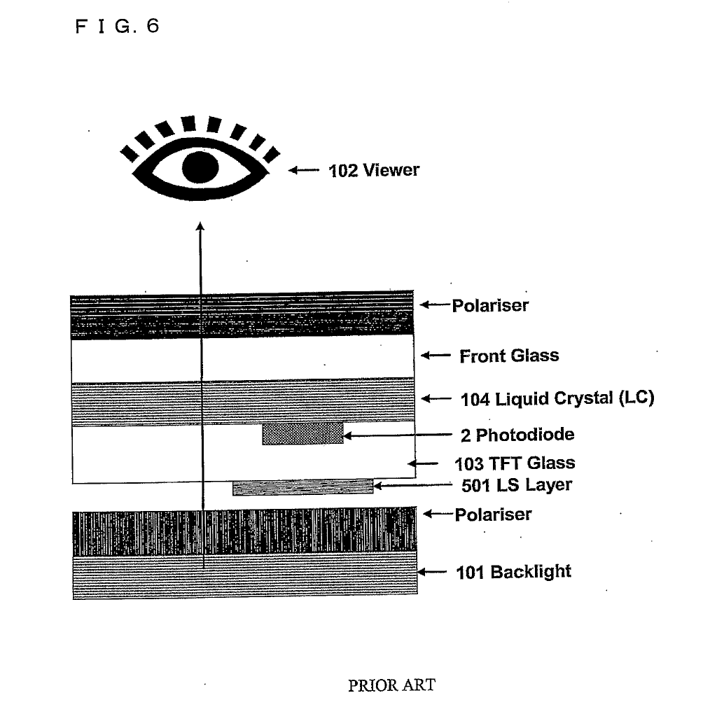

FIG. 7 shows prior art: a typical thin film PIN photodiode having a monolithically integrated LS layer;

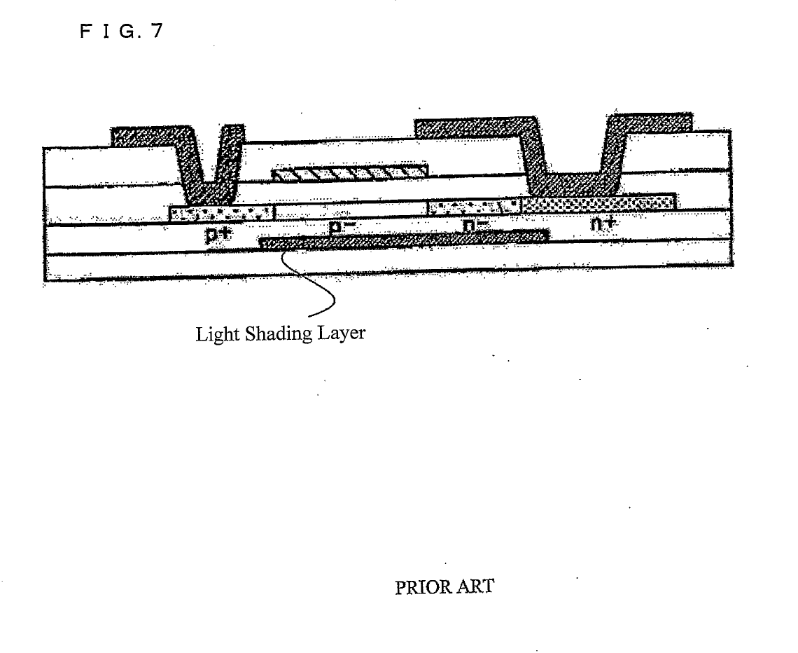

FIG. 8 shows prior art: a flowchart showing a typical AMLCD process which includes an LS layer;

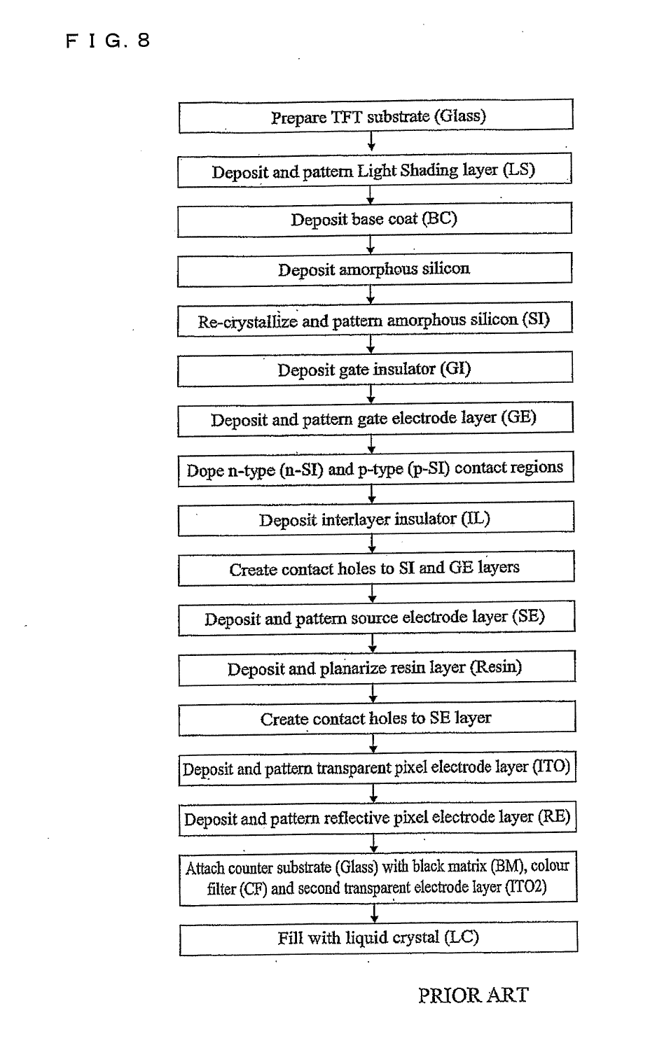

FIG. 9 shows prior art: a possible equivalent circuit for a thin film photodiode;

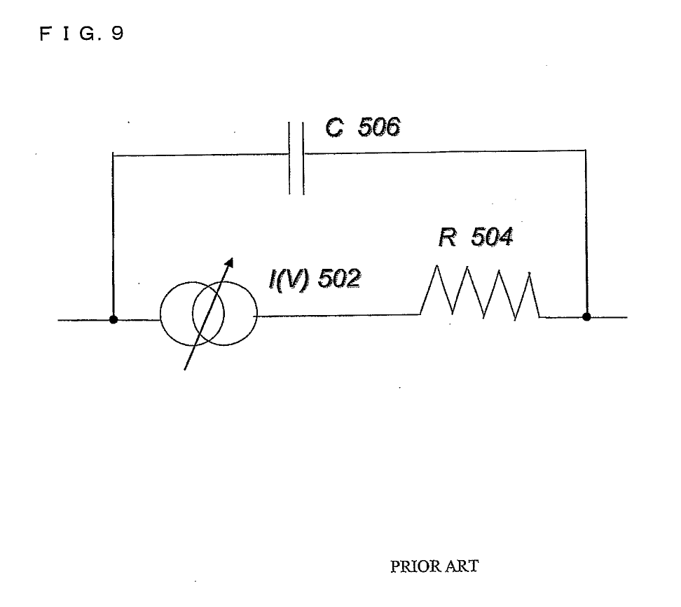

FIG. 10 shows prior art: series connected LDD-TFTs;

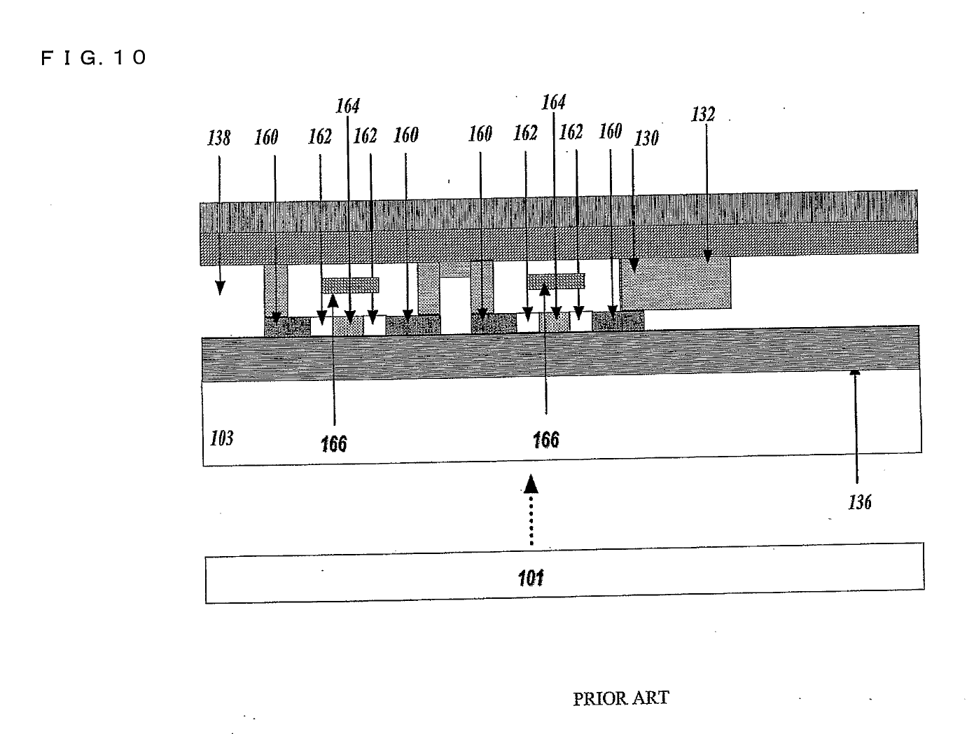

FIG. 11 shows prior art: a thin film photodiode with a light shading layer showing parasitic capacitive components;

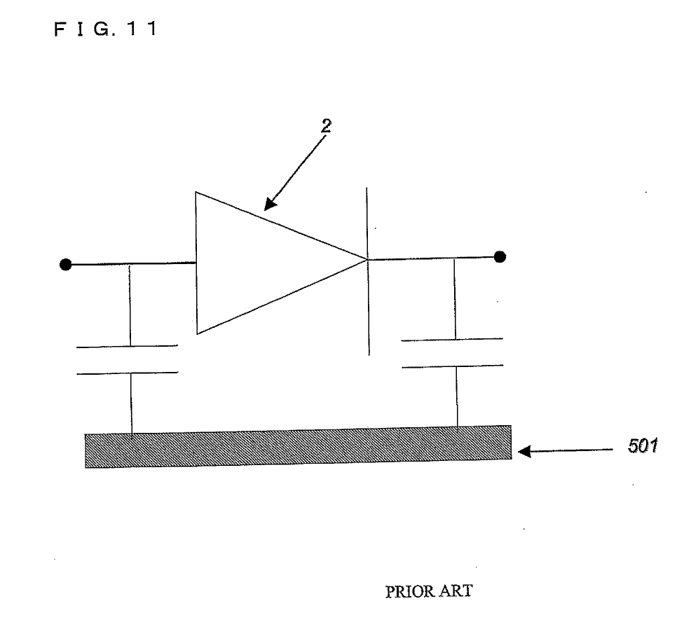

FIG. 12 shows prior art: a possible circuit implementation for biasing a photosensor device at zero volts and measuring the current generated;

FIG. 13 shows prior art: multiple photodiodes connected in series;

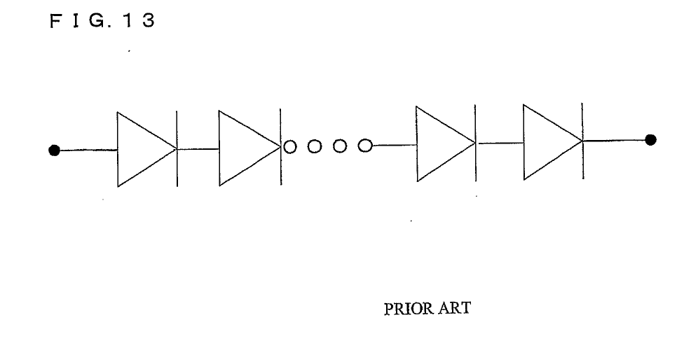

FIG. 14 shows prior art: a method for series connecting multiple photodiodes using contact to source electrode;

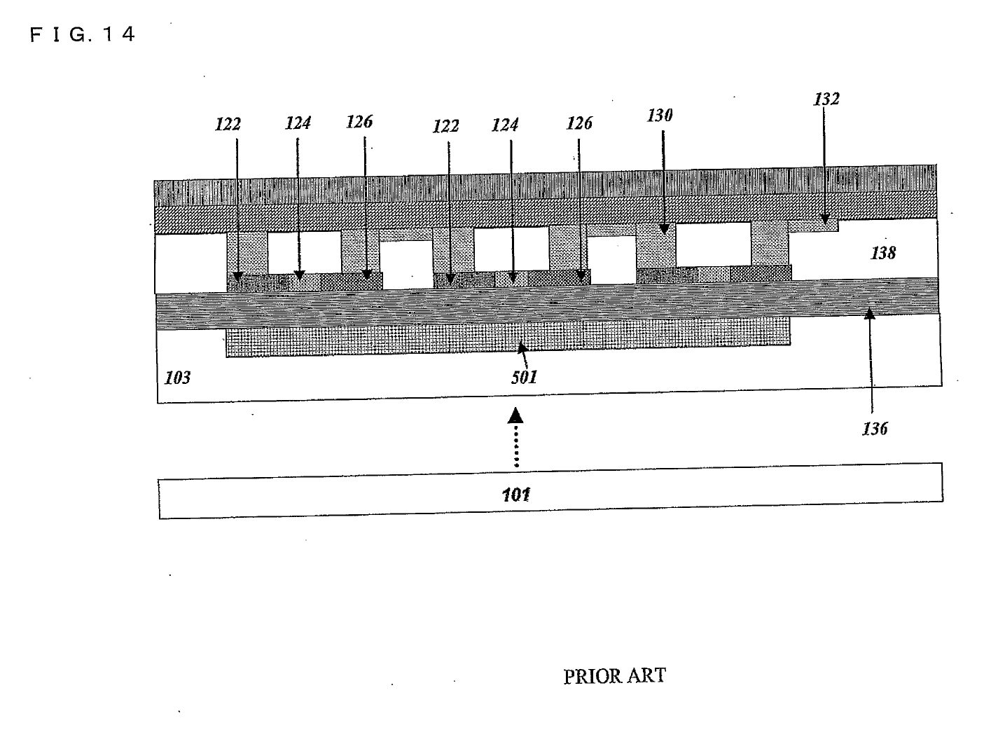

FIG. 15 shows prior art: an alternative method for series connecting multiple photodiodes using a PN structure;

FIG. 16 shows prior art: series connected photodiode elements with a light shading layer;

FIG. 17 shows prior art: an example of a detection and reference photodiode in a thin film process;

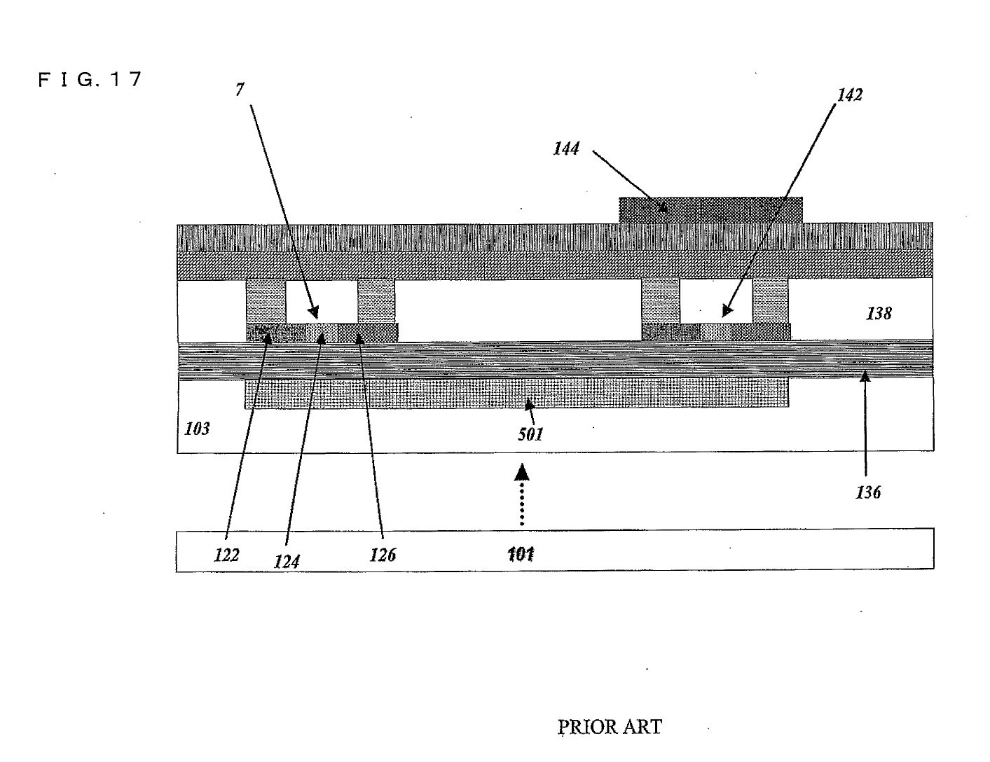

FIG. 18 shows prior art: a possible circuit implementation for measuring an ambient light level that has been corrected for the effects of stray light;

FIG. 19 shows a first embodiment of the invention;

FIG. 20 shows a schematic representation of the first embodiment;

FIG. 21 shows a second embodiment of the invention;

FIG. 22 shows a sixth embodiment of the invention;

FIG. 23 shows a seventh embodiment of the invention;

FIG. 24 shows an eighth embodiment of the invention;

FIG. 25 shows a ninth embodiment of the invention; and

FIG. 26 shows a tenth embodiment of the invention.

### DESCRIPTION OF EMBODIMENTS

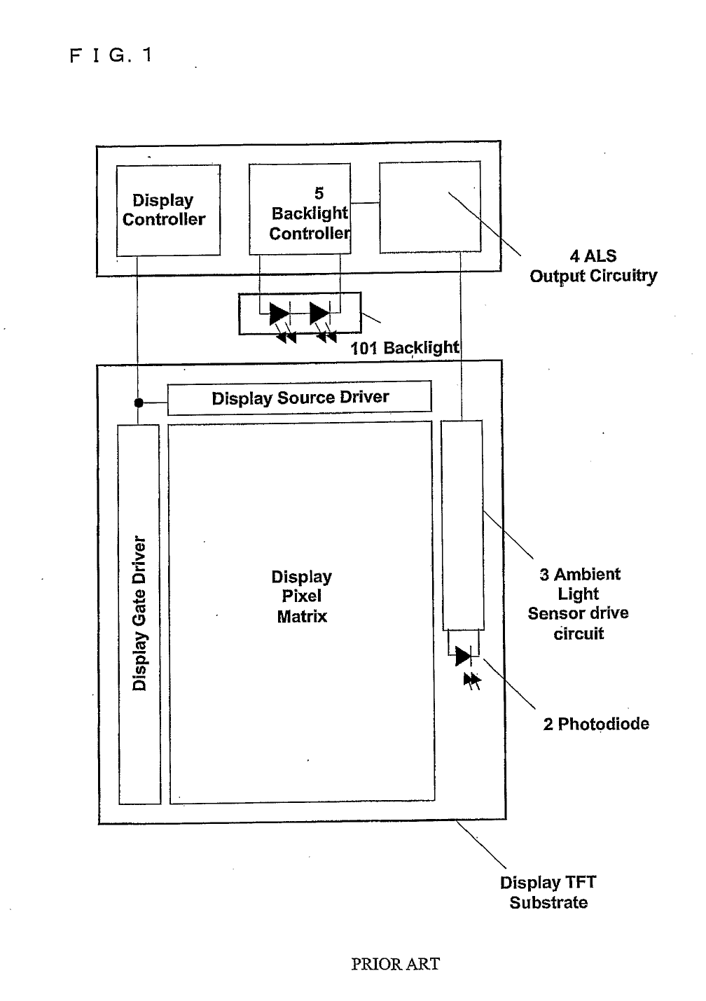

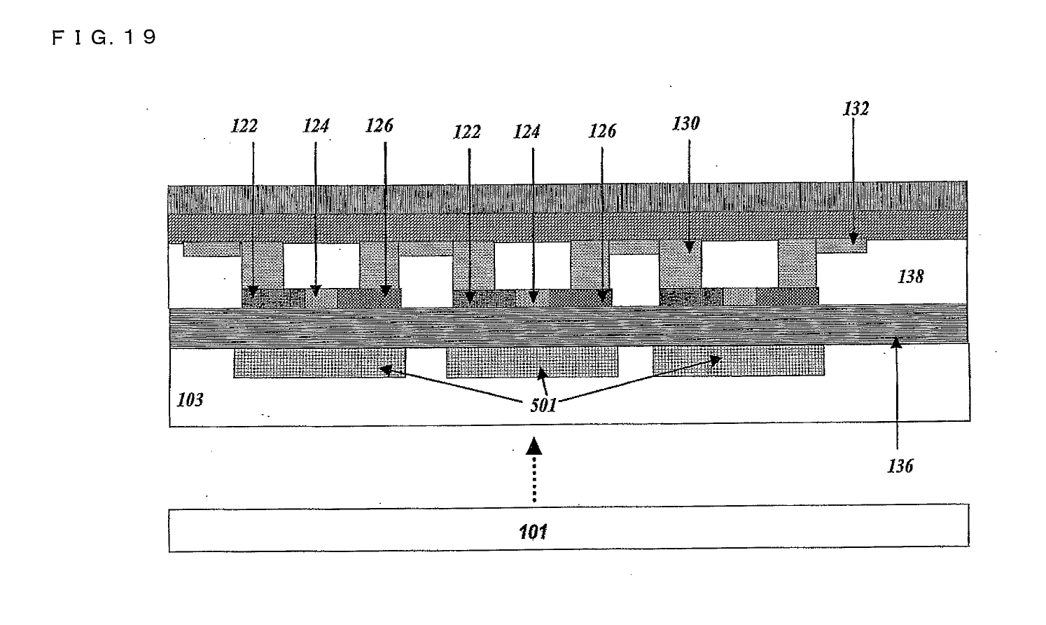

A first embodiment comprises an AMLCD with integrated ambient light sensor, as described in the prior art and shown in FIG. 1, with photodiode elements as shown in FIG. 19. This comprises, a number of photodiodes connected in series whose construction and operation are as has already been described in the prior art, with the exception that the light shading layer 501 is patterned to form multiple separate islands which are not electrically connected to one another or to any other conductive layer. The LS layer forms a first light shading layer and is patterned such that the opaque LS regions block the path of direct incidence from the backlight 101 to the photosensitive (lightly doped) region 124 of the photosensor element. The LS regions form conductive regions, for example comprising metallisation, isolated from the rest of the structure and shade the photosensitive regions of the photodiode elements from light incident on a first major surface comprising the lower surface of the AMLCD as shown in FIG. 19. The photosensitive regions extend laterally parallel to the first major surface and form lateral semiconductor junctions of PIN diodes. As an alternative, the photosensitive regions may comprise thin film transistors comprising part of a pixel circuit of the AMLCD.

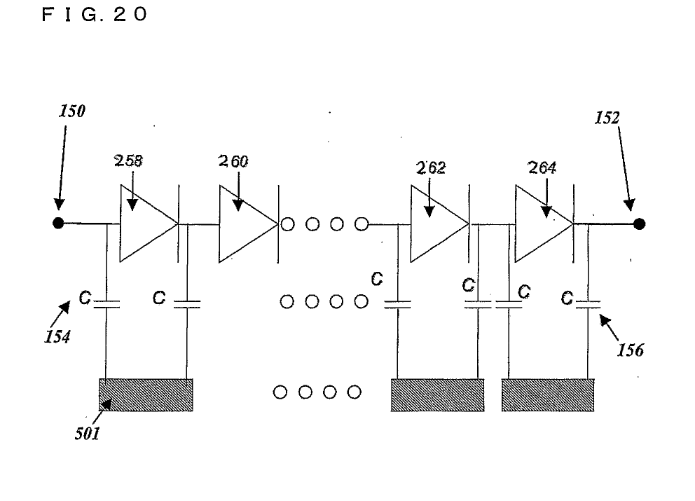

An advantage of patterning the LS layer 501 in this way is that the total parasitic capacitance from anode to cathode is considerably reduced. This can be understood with reference to the schematic of FIG. 20. To first order, the total capacitance CTOT2 between the anode 150 of the first photodiode 158 and the cathode 152 of the Nth photodiode 164 is that due to 2N capacitors of value C arranged in series, i.e.

$${C}_{TOT 2} = \frac{1}{{\sum }_{x = 1}^{2 N} ( 1 / C )} = \frac{C}{2 N} \qquad ( 2 )$$

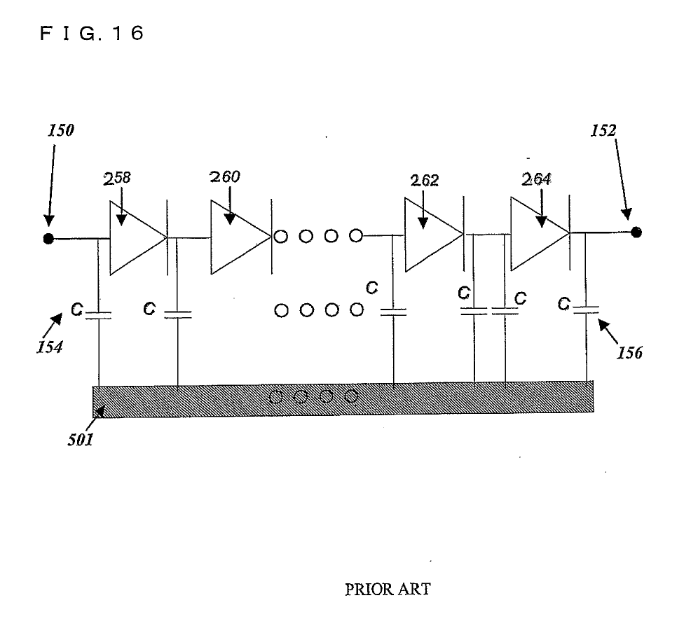

The total parasitic capacitance is reduced by a factor of N compared to the prior art structure of FIG. 16. This simple model (whereby lateral capacitances between the different LS islands have been taken to be small) illustrates how segmenting the LS layer into multiple islands can greatly reduce the parasitic capacitance of series connected photosensor devices.

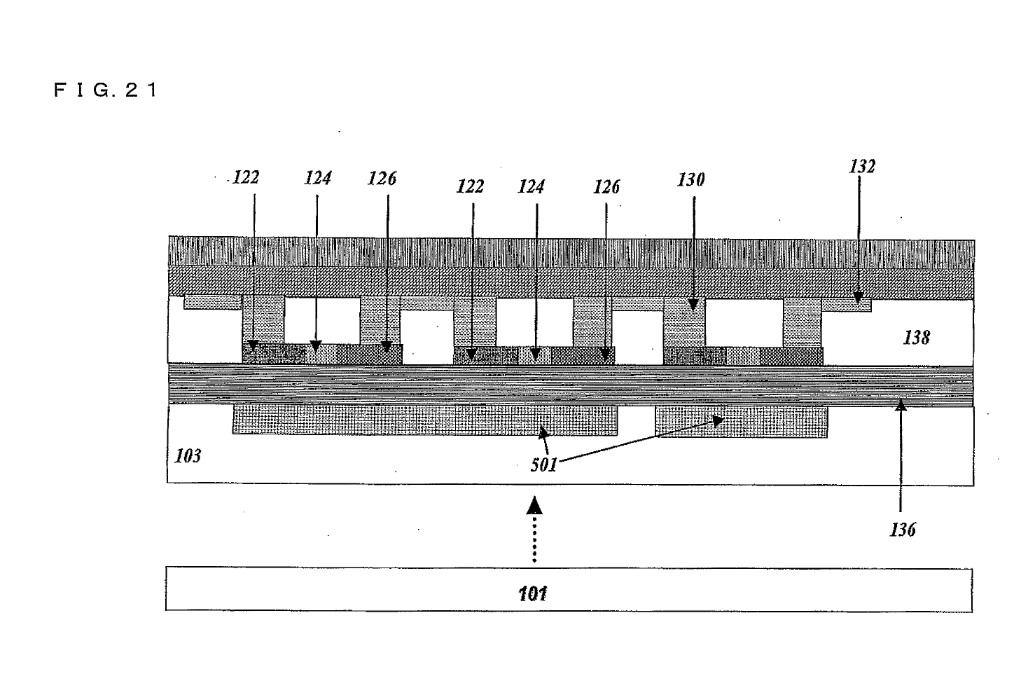

The second embodiment is shown in FIG. 21. This embodiment is as the first embodiment, except that the LS layer is patterned so that the “breaks” formed are not between every photosensor. According to this embodiment, if the number of series connected photosensors is N, then the number of separate LS islands will be between 2 and N−1.

One advantage of this embodiment is in the case where segmenting the LS layer requires the lateral separation of the photosensors to be greater than for a continuous LS layer island. According to this embodiment, the total parasitic capacitance may be reduced by having a number of separate LS islands greater than 1, but without increasing the total layout area as much as would be the case if the total number of LS islands was the same as the number of photosensor elements.

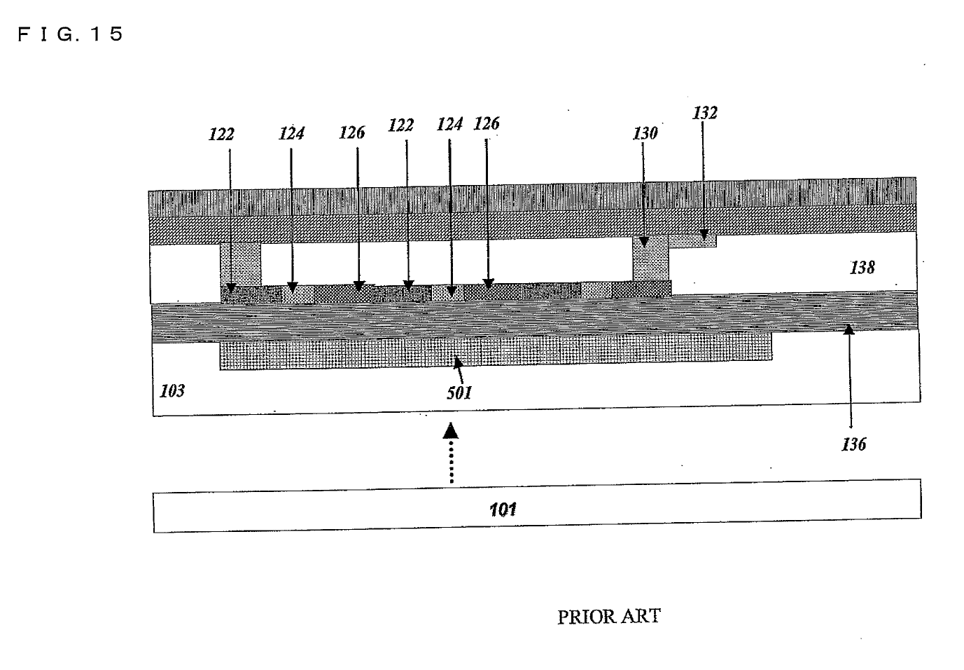

The third embodiment is as either of embodiments one or two, and where the series connected photosensors are connected together using a PN contact structure as described in the prior art and shown in FIG. 15.

The fourth embodiment is as either of embodiments one or two, and where the series connected photosensors are connected together such that some connections are formed by contacts to the SE metal layer and other contacts are formed by the PN contact structure as previously described.

The fifth embodiment is as any of the previous embodiments where the photosensor element has an additional light blocking layer to block the incidence of ambient light, as described in prior art. For example, the additional light blocking layer forms a second light shading layer which shades the photosensitive regions from light incident on a second major surface comprising the upper surface of the AMLCD as shown in FIG. 19.

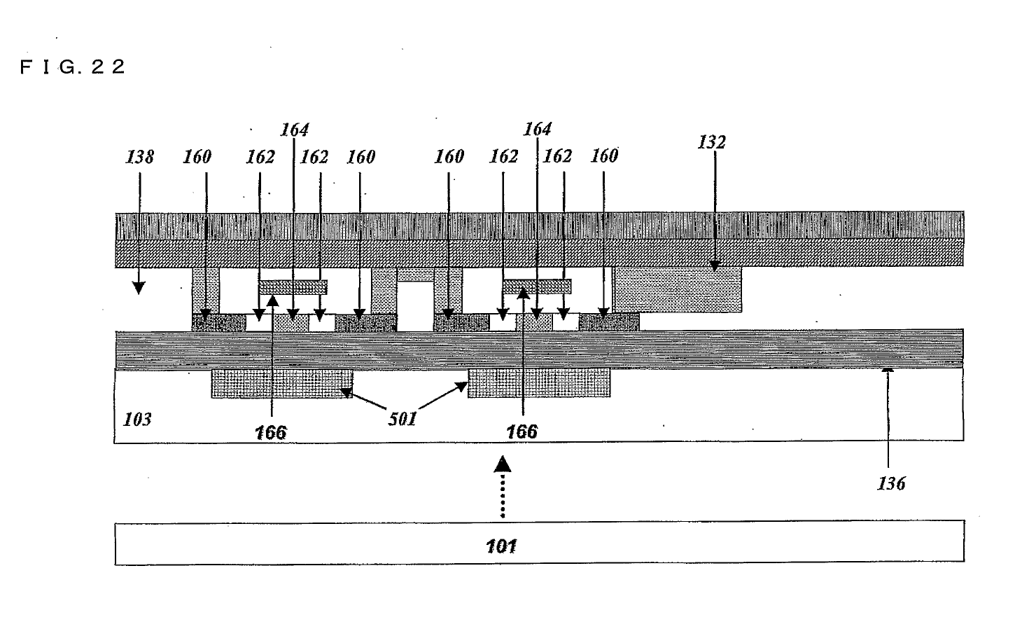

The sixth embodiment is as any of the previous embodiments where the photosensor element is a phototransistor shown in FIG. 22. This embodiment comprises multiple LDD-TFTs connected in series (two are shown; a greater number is also possible). An LS layer segmented into two sections is used to block directly incident illumination from the backlight.

This embodiment could be advantageously realised as a sensor element comprised of series connected photo-TFTs, the principles of operation and advantages of which are as has already been described for the first embodiment.

It will be apparent to one skilled in the art that the invention can also be implemented with any other type of photosensor device where multiple devices are connected in series or where the device has multiple photosensitive regions.

A further implementation of the sixth embodiment is in a pixel-TFT structure designed for low leakage. By use of multiple series TFTs, leakage current can be reduced as described in the prior art. An advantage of segmenting the LS layer is that the benefit of reduced photo-generated leakage current can be combined with reduced parasitic capacitance between the drain of the first series device and the source of the last series device.

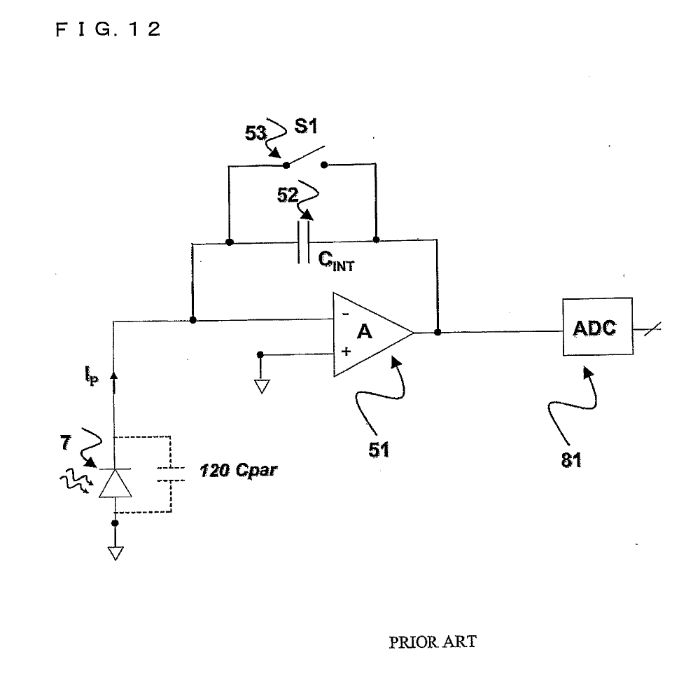

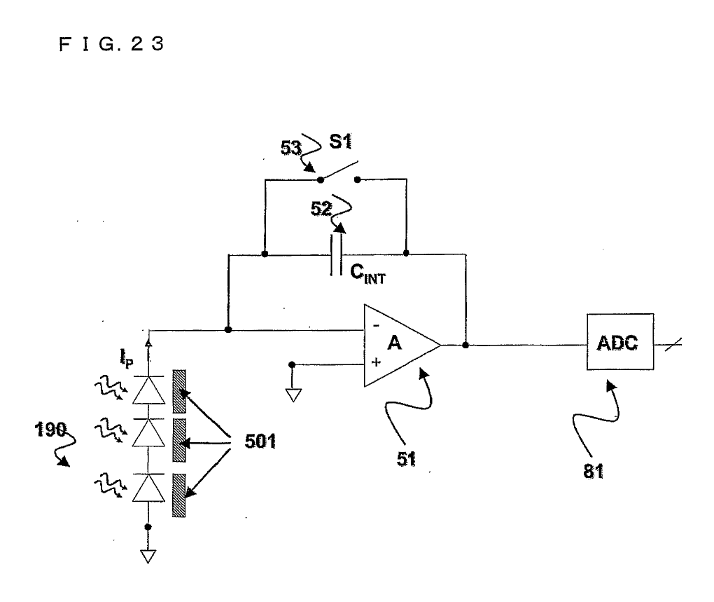

The seventh embodiment is shown in FIG. 23. This embodiment comprises the ALS circuit of FIG. 12 whose construction and operation has been described in the prior art, and where additionally the photosensor element 190 comprises multiple series photodiodes which have a segmented LS layer according to any of embodiments one to five. It will be apparent to one skilled in the art that there are many possible other circuit architectures which could alternatively be used to measure the photocurrent generated by the photosensor elements.

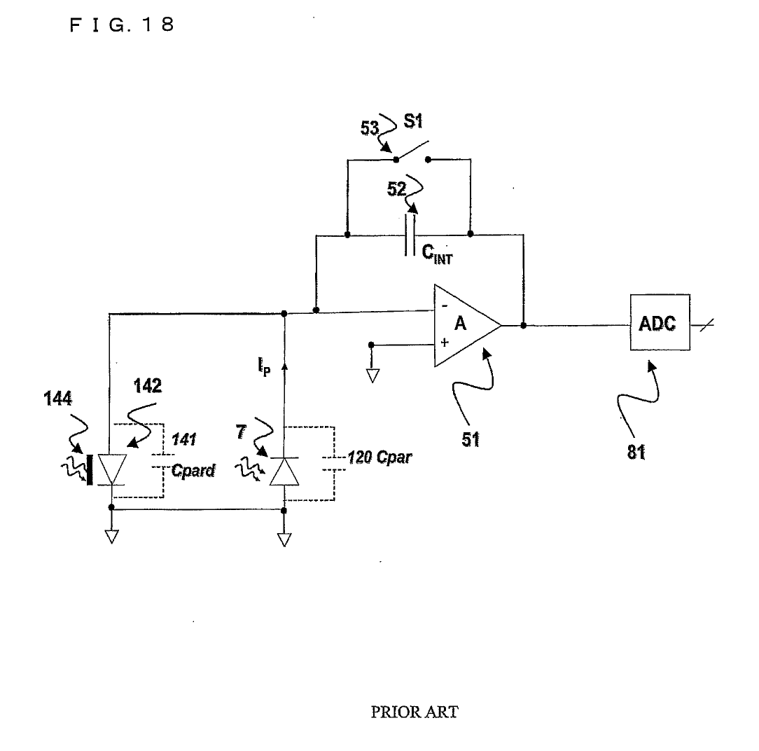

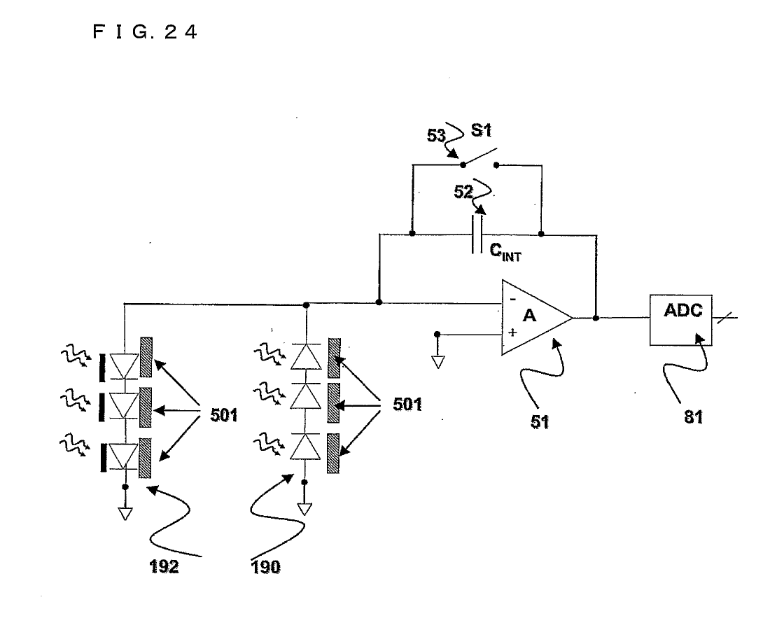

The eighth embodiment is shown in FIG. 24. This embodiment consists of the ALS circuit of FIG. 18 whose construction and operation has been described in the prior art, and where additionally the reference photosensor element 192 and the detection photosensor element 190 both comprise multiple series photodiodes which have a segmented LS layer according to any of embodiments one to five. It will be apparent to one skilled in the art that there are many possible other circuit architectures which could alternatively be used to measure the photocurrent generated by the photosensor elements and subtract the two results to give an output that is representative of the ambient light level, the effects of stray light having been compensated for.

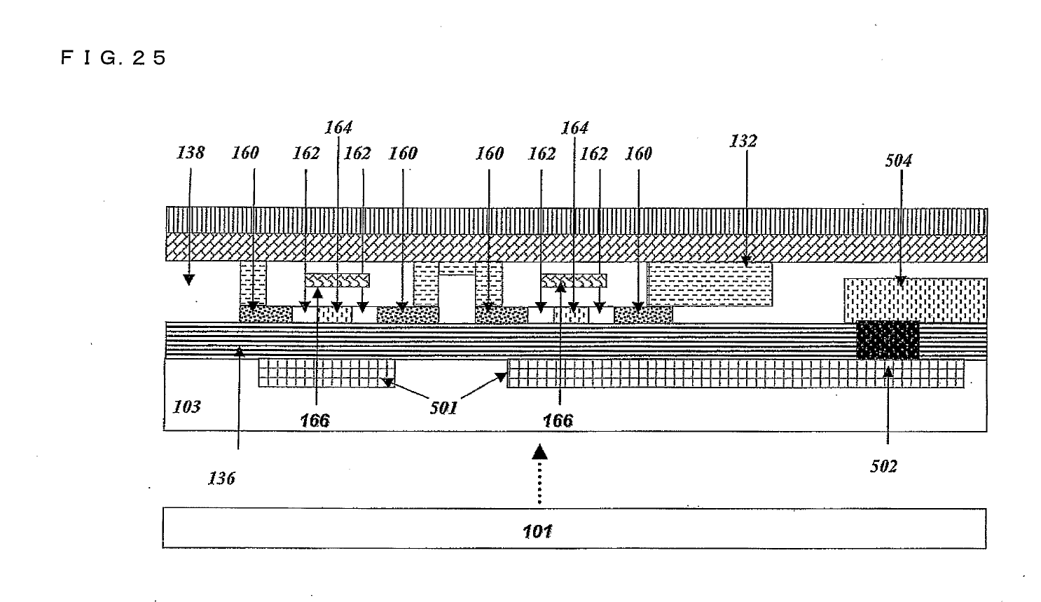

The ninth embodiment is shown in FIG. 25. This embodiment is as any of the previous embodiments, where an electrical contact 502 is made to one or more of the light shading layer structures to electrically connect it to another conductive layer 504 (which may for example be the source electrode). An advantage of this embodiment is that the potential of one or more of the light shading layers may be controlled directly, for example by being connected to a predetermined potential. This may be beneficial if the photosensor element 2 has operating characteristics that are influenced by the capacitive effect of the light shading layer.

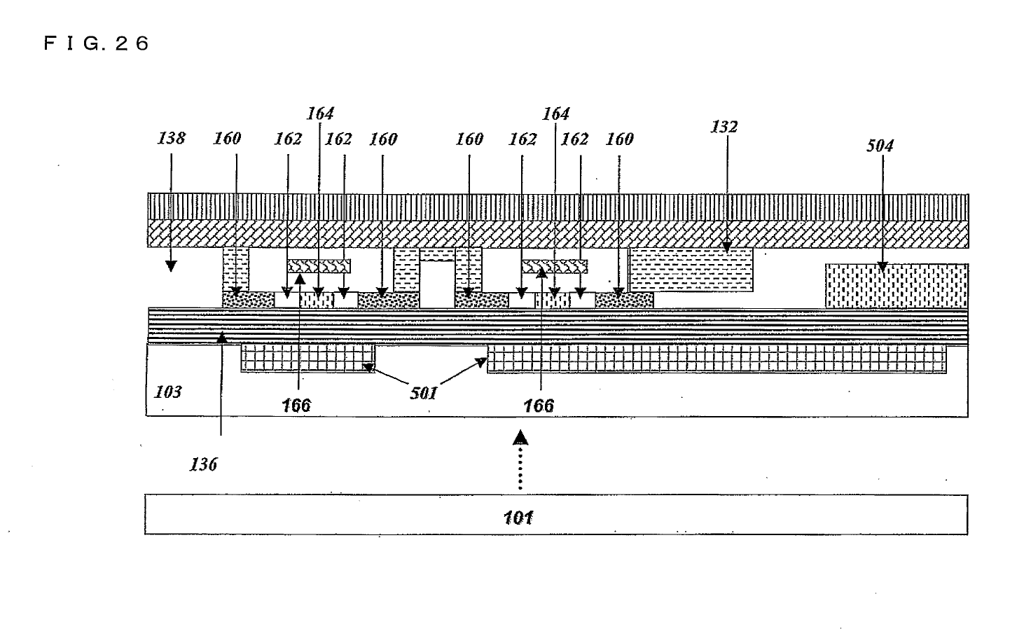

The tenth embodiment is shown in FIG. 26. This embodiment is as the ninth embodiment except that the potential of one or more light shading structures is controlled capactively, for example by a capacitive connection to a predetermined potential. FIG. 26 shows an example implementation. A capacitor is created whose plates consist of the light shading layer material and another conductive layer 504, which may for example be the source electrode. By controlling the potential applied to the conductive layer 504, the potential of the light shading layer is also controlled. An advantage of the tenth embodiment is that it is not necessary to form a direct electrical contact between the light shading layer and the conductive layer used to control its potential.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

1. A photosensitive structure comprising a plurality of photosensitive regions which are electrically in series and a first light shading layer comprising a plurality of electrically conductive regions disposed so as to shade the photosensitive regions from light incident on a first major surface of the structure, the conductive regions being electrically isolated from each other.

2. A structure as claimed in claim 1, in which the photosensitive regions extend laterally parallel to the first major surface.

3. A structure as claimed in claim 2, in which the photosensitive regions comprise a plurality of lateral semiconductor junctions.

4. A structure as claimed in claim 3, in which the photosensitive regions comprise PIN diodes.

5. A structure as claimed in claim 3, in which the photosensitive regions comprise thin film transistors.

6. A structure as claimed in claim 5, in which the thin film transistors comprise part of a pixel circuit of an active matrix device.

7. A structure as claimed in claim 1, in which the photosensitive regions comprise photosensor elements.

8. A structure as claimed in claim 1, comprising a second light shading layer comprising a plurality of electrically conductive regions disposed so as to shade the photosensitive regions from light incident on a second major surface of the structure and electrically isolated from each other.

9. A structure as claimed in claim 1, in which the conductive regions comprise metallisation.

10. A structure as claimed in claim 1, in which the conductive regions are electrically isolated from the rest of the structure.

11. A structure as claimed in claim 1, in which at least one of the conductive region is arranged to be connected to a predetermined potential.

12. A structure as claimed in claim 11, in which the at least one conductive region is connected via a capacitive connection.

13. A structure as claimed in claim 1, in which each of the conductive regions of the first light shading layer is associated with a respective one of the photosensitive regions.

14. A structure as claimed in claim 1, in which at least one of the conductive regions of the first light shading layer is arranged to shade at least two of the photosensitive regions from light incident on the first major surface.

15. A structure as claimed in claim 1, formed on an active matrix substrate.

16. An ambient light sensor comprising a structure as claimed in claim 1.

17. A sensor as claimed in claim 16, comprising a further structure as claimed in any one of the preceding claims arranged to act as a reference.

18. An apparatus including a structure as claimed in claim 1.

19. An apparatus as claimed in claim 18, comprising a liquid crystal device.

20. An apparatus as claimed in claim 18, comprising a display.

21. An apparatus as claimed in claim 20, comprising a backlight, the first light shading layer being disposed between the photosensitive regions and the backlight.
